(19) United States
(12) Patent Application Publication
(10) Pub. No.: US 2013/0033834 A1
(43) Pub. Date: Feb. 7, 2013

(54) Flat Panel Display Apparatus, Mother Substrate for Flat Panel Display Apparatus, Method of Manufacturing Flat Panel Display Apparatus, and Method of Manufacturing Mother Substrate for Flat Panel Display Apparatus

(71) Applicants: Oh-Seob Kwon, Yongin-City (KR); Jae-Sang Ro, Seoul (KR); Seog-Young Lee, Seoul (KR); Won-Eui Hong, Seoul (KR)

(72) Inventors: Oh-Seob Kwon, Yongin-City (KR); Jae-Sang Ro, Seoul (KR); Seog-Young Lee, Seoul (KR); Won-Eui Hong, Seoul (KR)

(73) Assignees: Ensil Tech Co., Ltd., Seoul (KR); Samsung Mobile Display Co., Ltd., Yongin-City (KR)

(21) Appl. No.: 13/523,159

(22) Filed: Jun. 14, 2012

(30) Foreign Application Priority Data
Aug. 3, 2011 (KR) 10-2011-0077367

(51) Int. Cl. H05K 7/06; H01J 9/26

(52) U.S. Cl. 361/760; 445/25

(57) ABSTRACT

A flat panel display apparatus may include: a substrate; a display portion arranged on the substrate; an encapsulation substrate arranged to face the display portion; a sealing portion arranged between the substrate and the encapsulation substrate and surrounding the display portion; a wiring portion arranged between the substrate and the encapsulation substrate and having an area overlapping the sealing portion, and comprising a plurality of wiring members having different respective resistances; and a lead-in portion connected to the wiring portion and an external power source for applying a voltage to the wiring portion.

### CLAIM OF PRIORITY

This application makes reference to, incorporates the same herein, and claims all benefits accruing under 35 U.S.C. §119 from an application earlier filed in the Korean Intellectual Property Office on the 3^{rd} of Aug. 2011 and there duly assigned Serial No. 10-2011-0077367.

### BACKGROUND OF THE INVENTION

1. Field of the Invention

The present invention relates to a flat panel display apparatus, a mother substrate for a flat panel display apparatus, a method of manufacturing a flat panel display apparatus, and a method of manufacturing a mother substrate for a flat panel display apparatus, and more particularly, to a flat panel display apparatus having improved encapsulation characteristic, a mother substrate for a flat panel display apparatus, a method of manufacturing a flat panel display apparatus, and a method of manufacturing a mother substrate for a flat panel display apparatus.

2. Description of the Related Art

Recently, display apparatuses are being replaced by portable, thin flat panel display apparatuses. In particular, flat panel display apparatuses, such as organic light emitting display apparatuses and liquid crystal display apparatuses, are widely accepted due to their high image quality.

In a flat panel display apparatus, a display portion is arranged on a substrate and an encapsulation substrate is arranged above the display portion to protect the display portion. Also, a sealing portion is arranged between the substrate and the encapsulation substrate.

For convenience of manufacture, after a mother substrate for a flat panel display device in which a plurality of display portions and sealing portions are formed between the substrate and the encapsulation substrates is completed, the mother substrate is cut by each display portion so that a single flat panel display apparatus is formed for each display portion.

Also, a flat panel display apparatus undergoes an encapsulation process to protect a display portion from external moisture, gas, and other foreign materials. The quality of a flat panel display apparatus is greatly affected by an encapsulation characteristic. The encapsulation characteristic is dominated by the encapsulation substrate and the sealing portion. Since a process of forming the sealing portion is difficult, there is a limit in improving the encapsulation characteristic.

### SUMMARY OF THE INVENTION

The present invention provides a flat panel display apparatus having improved encapsulation characteristic, a mother substrate for a flat panel display apparatus, a method of manufacturing a flat panel display apparatus, and a method of manufacturing a mother substrate for a flat panel display apparatus.

According to an aspect of the present invention, a flat panel display apparatus may include a substrate, a display portion arranged on the substrate, an encapsulation substrate arranged to face the display portion, a sealing portion arranged between the substrate and the encapsulation substrate so as to surround the display portion, a wiring portion arranged between the substrate and the encapsulation substrate so as to have an area overlapping the sealing portion and comprising a plurality of wiring members having different resistance, and a lead-in portion connected to the wiring portion for applying a voltage to the wiring portion and electrically connected to an external power source.

The sealing portion may include a plurality of sealing members corresponding to the respective wiring members.

The plurality of sealing members may be formed of different materials.

The plurality of sealing members may be formed of the same material.

The lead-in portion may include a plurality of lead-in members corresponding to the respective wiring members.

The plurality of lead-in members may be separated from each other.

The plurality of wiring members may be separated from each other.

The plurality of wiring members may include a first wiring member surrounding the display portion, and a second wiring member surrounding at least the first wiring portion.

The lead-in portion may include a first lead-in member corresponding to the first wiring member, and a second lead-in member corresponding to the second wiring member, wherein the second lead-in member is arranged at both sides of the first lead-in member.

Each of the plurality of wiring members may include a plurality of wirings.

The plurality of wirings may be separated from each other.

The plurality of wirings may be formed on the substrate, and the sealing portion may be arranged on an upper surface of the wiring and in an interval space between neighboring wirings of the plurality of wirings.

The plurality of wirings may include a wiring having a curved corner portion.

An area of the lead-in portion that is connected to the plurality of wirings may have a width decreasing toward the display portion so as to have an angled shape.

At least one of the plurality of wiring members may include a plurality of wirings and at least one of the plurality of wiring members is integrally formed.

An area of the lead-in portion that is connected to the plurality of wirings may have a width decreasing toward the display portion so as to have an angled shape.

At least one of the plurality of wiring members may include an integrated area that is integrally formed at least in a partial area and may include a plurality of wirings that are connected to the integrated area and separated from each other.

The plurality of wirings that are separated from each other may be arranged to correspond to corners of the display portion.

The plurality of wirings that are separated from each other may be formed so as to be bent.

The plurality of wirings that are separated from each other may be connected to the lead-in portion.

An area of the lead-in portion that is connected to the plurality of wirings may have a width decreasing toward the display portion so as to have an angled shape.

The lead-in portion may be formed so as to correspond to one corner of the display portion and another corner of the display portion.

The lead-in portion may be symmetrically arranged with respect to a center of the display portion.

The lead-in portion may be formed so as to have a width greater than that of the wiring portion.

The display portion may include an organic light emitting device.

According to another aspect of the present invention, a mother substrate for a flat panel display apparatus may include a substrate, a plurality of display portions arranged on the substrate and separated from each other so as to form a plurality of flat panel display apparatuses, an encapsulation substrate arranged to face the plurality of display portions, a plurality of sealing portions arranged between the substrate and the encapsulation substrate so as to surround each of the display portions, a plurality of wiring portions arranged between the substrate and the encapsulation substrate so as to have an area overlapping each of the plurality of sealing portions, each wiring portion comprising a plurality of wiring members having different resistance, a connection portion containing a conductive material and arranged to connect ones of the plurality of wiring portions that are adjacent to each other in one direction, and a lead-in portion connected to the plurality of wiring portions so as to apply a voltage to the plurality of wiring portions and electrically connected to an external power.

The connection portion may include a plurality of connection members corresponding to the respective wiring members.

The plurality of connection members may be separated from each other.

At least one of the plurality of wiring members may include a plurality of wirings, and an area of the connection portion that is connected to the plurality of wirings may have a width decreasing toward the display portion so as to have an angled shape.

At least one of the plurality of wiring members may include an integrated area that is integrally formed in at least one area and a plurality of wirings separated from each other in at least one area.

An area of the connection portion that is connected to the plurality of wirings may have a width decreasing toward the display portion so as to have an angled shape.

The connection portion may have a width greater than that of the wiring portion.

According to another aspect of the present invention, a method of manufacturing a flat panel display apparatus may include preparing a substrate on which a display portion is arranged, arranging an encapsulation substrate to face the display portion, forming a sealing portion between the substrate and the encapsulation substrate so as to surround the display portion, forming a wiring portion between the substrate and the encapsulation substrate so as to overlap at least the sealing portion and comprising a plurality of wiring members having different resistance, and forming a lead-in portion electrically connected to an external power and the wiring portion, wherein the forming of the sealing portion may include arranging a material for forming the sealing portion between the substrate and the encapsulation substrate, electrically connecting the external power to the lead-in portion, applying a voltage generated from the external power to the wiring portion through the lead-in portion, and melting and curing the material for forming the sealing portion using heat generated from the wiring portion.

The forming of the sealing portion may include forming a plurality of sealing members respectively corresponding to the plurality of wiring members.

According to another aspect of the present invention, a method of manufacturing a flat panel display apparatus may include preparing a substrate on which a plurality of display portions are arranged to form a plurality of flat panel display apparatuses, arranging an encapsulation substrate to face the plurality of display portions, forming a sealing portion between the substrate and the encapsulation substrate so as to surround each display portion, forming a plurality of wiring portions between the substrate and the encapsulation substrate so as to overlap at least the sealing portion, each of the plurality of wiring portions comprising a plurality of wiring members having different resistance, forming a connection portion containing a conductive material and arranged to connect ones of the plurality of wiring portions that are adjacent to each other in one direction, and forming a lead-in portion electrically connected to an external power source and the plurality of wiring portions, wherein the forming of the sealing portion includes arranging a material for forming the sealing portion between the substrate and the encapsulation substrate, electrically connecting the external power source to the lead-in portion, applying a voltage generated from the external power source to the plurality of wiring portions through the lead-in portion, and melting and curing the material for forming the sealing portion using heat generated from the plurality of wiring portions.

The forming of the sealing portion may include forming a plurality of sealing members respectively corresponding to the plurality of wiring members.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic plan view of a flat panel display apparatus according to an embodiment of the present invention;

FIG. 2 is a cross-sectional view taken along line II-II of FIG. 1;

FIG. 3 is an enlarged view of a portion X of FIG. 2;

FIG. 4 is a plan view schematically illustrating an operation of applying a voltage to form a sealing portion in a process of manufacturing the flat panel display apparatus of FIG. 1;

FIG. 5 is a schematic plan view of a flat panel display apparatus according to another embodiment of the present invention;

FIG. 6 is a cross-sectional view taken along line VI-VI of FIG. 5;

FIG. 7 is a schematic plan view of a flat panel display apparatus according to another embodiment of the present invention;

FIG. 8 is a cross-sectional view taken along line VIII-VIII of FIG. 7;

FIG. 9 is a schematic plan view of a flat panel display apparatus according to another embodiment of the present invention;

FIG. 10 is a schematic plan view of a flat panel display apparatus according to another embodiment of the present invention;

FIG. 11 is a schematic plan view of a flat panel display apparatus according to another embodiment of the present invention;

FIG. 12 is a schematic plan view of a mother substrate for a flat panel display apparatus according to an embodiment of the present invention;

FIG. 13 is a plan view schematically illustrating an operation of applying a voltage to form a sealing portion in a process of manufacturing the mother substrate for a flat panel display apparatus of FIG. 12;

FIG. 14 is a schematic plan view of a mother substrate for a flat panel display apparatus according to another embodiment of the present invention; and

FIG. 15 is a schematic plan view of a mother substrate for a flat panel display apparatus according to another embodiment of the present invention.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

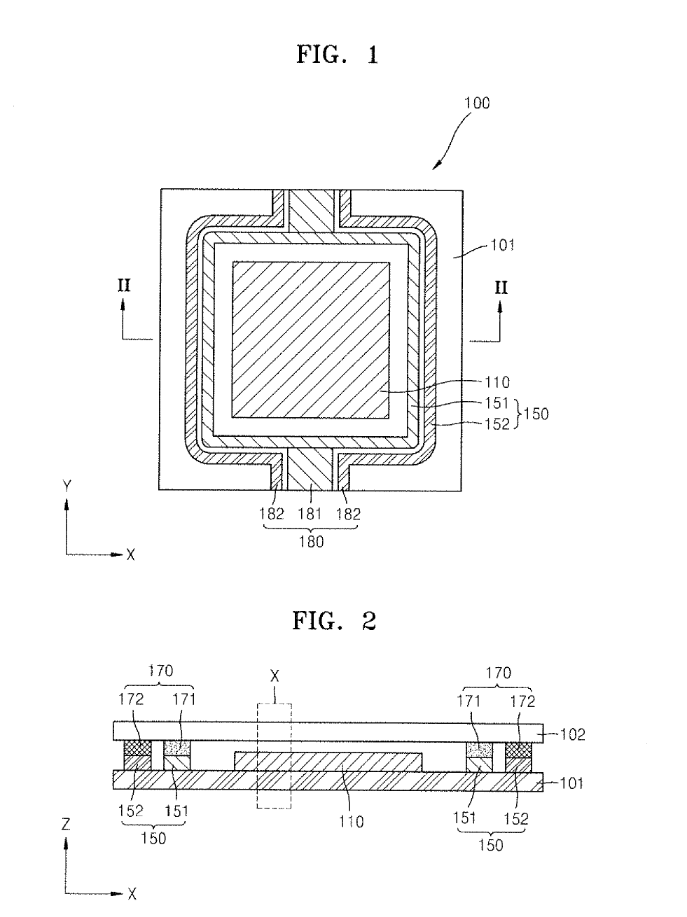

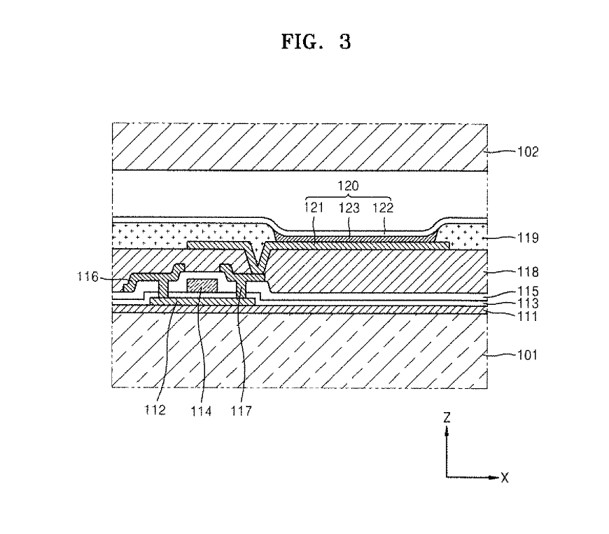

FIG. 1 is a schematic plan view of a flat panel display apparatus according to an embodiment of the present invention; FIG. 2 is a cross-sectional view taken along line II-II of FIG. 1; and FIG. 3 is an enlarged view of a portion X of FIG. 2.

Referring to FIGS. 1-3, the flat panel display apparatus 100 according to the present embodiment includes a substrate 101, a display portion 110, an encapsulation substrate 102, a wiring portion 150, a sealing portion 170, and a lead-in portion 180. For easy understanding of the present invention, the sealing portion 170 is not illustrated in FIG. 1, but is illustrated in FIG. 2.

In detail, the substrate 101 may be formed of a transparent glass material containing SiO₂ as a main ingredient. The substrate 101 is not limited thereto and may be formed of a transparent plastic material. The plastic material forming the substrate 101 may be an organic material selected from the group consisting of polyethersulphone (PES), polyacrylate (PAR), polyetherimide (PEI), polyethylene napthalate (PEN), polyethyleneterepthalate (PET), polyphenylene sulfide (PPS), polyallylate, polyimide, polycarbonate (PC), triacetyl cellulose (TAC), cellulose acetate propionate (CAP).

Also, the substrate 101 may be formed of metal.

The display portion 110 is arranged on the substrate 101. The display portion 110 may be any one of a variety of types. Although, in the present embodiment, the display portion 110 includes an organic light emitting device 120, the present invention is not limited thereto and may include various types of display devices.

The encapsulation substrate 102 is arranged to face the display portion 110. The sealing portion 170 is arranged between the substrate 101 and the encapsulation substrate 102.

The sealing portion 170 includes a first sealing member 171 and a second sealing member 172. The first sealing member 171 surrounds the display portion 110. The first sealing member 171 facilitates coupling between the substrate 101 and the encapsulation substrate 102. The second sealing member 172 surrounds the first sealing member 171. The second sealing member 172 also facilitates coupling between the substrate 101 and the encapsulation substrate 102.

The first sealing member 171 and the second sealing member 172 may contain various materials. That is, the first sealing member 171 may contain frit and the second sealing member 172 may contain thermosetting resin. Conversely, the first sealing member 171 may contain thermosetting resin and the second sealing member 172 may contain frit.

Also, the present invention is not limited thereto, and both of the first and second sealing members 171 and 172, respectively, may contain the same material, for example, frit.

The wiring portion 150 is arranged to overlap the sealing portion 170 and includes a first wiring member 151 and a second wiring member 152. The first wiring member 151 and the second wiring member 152 are separated from each other.

The first and second wiring members 151 and 152, respectively, of the wiring portion 150 may be formed of a variety of conductive materials, and may be formed of different materials so as to have different resistances.

That is, the first and second wiring members 151 and 152, respectively, have different resistances so that different Joule heat is generated in the first and second wiring members 151 and 152, respectively, when a voltage is applied to the first and second wiring members 151 and 152, respectively, in a subsequent process.

For example, when the first sealing member 171 contains thermosetting resin and the second sealing member 172 contains frit, the resistance of the first wiring member 151 is lower than that of the second wiring member 152. In this case, when a voltage is applied to the first and second wiring members 151 and 152, respectively, in a subsequent process, the amount of Joule heat generated from the first wiring member 151 is less than that of the Joule heat generated from the second wiring member 152. This is because more heat is needed to melt and cure a material containing frit than to melt and cure thermosetting resin. That is, different Joule heat may be generated from the first and second wiring members 151 and 152, respectively, by connecting one external power to the first and second wiring members 151 and 152, respectively, and simultaneously applying a voltage to the first and second wiring members 151 and 152, respectively.

The first wiring member 151 surrounds the display portion 110. The second wiring member 152 surrounds the first wiring member 151. The first wiring member 151 is arranged to overlap the first sealing member 171. The second wiring member 152 is arranged to overlap the second sealing member 172.

The first and second wiring members 151 and 152, respectively, are formed on the substrate 101. The first sealing member 171 is formed on the first wiring member 151. The second sealing member 172 is formed on the second wiring member 152. The encapsulation substrate 102 is arranged on the first and second sealing members 171 and 172, respectively.

The width of the first wiring member 151 may correspond to the width of the first sealing member 171 or may be slightly greater than or smaller than the width of the first sealing member 171 according to a process condition. Likewise, the width of the second wiring member 152 may correspond to the width of the second sealing member 172 or may be slightly greater than or smaller than the width of the second sealing member 172 according to a process condition.

The lead-in portion 180 is connected to the wiring portion 150. The lead-in portion 180 includes a first lead-in member 181 and a second lead-in member 182. The first lead-in member 181 is connected to the first wiring member 151. The second lead-in member 182 is connected to the second wiring member 152. The second lead-in member 182 is arranged at both sides of the first lead-in member 181 so as to be separated from the first lead-in member 181.

The lead-in portion 180 is connected to an external power source (not shown) in a process of forming the sealing portion 170 during the manufacture of the flat panel display apparatus 100. A voltage generated by the external power source is applied to the wiring portion 150 via the lead-in portion 180 so that Joule heat is generated in the wiring portion 150. A material for forming the sealing portion 170 is melted and cured using the Joule heat, thereby forming the sealing portion 170.

The lead-in portion 180 may be formed of the same material as the wiring portion 150. That is, the first lead-in member 181 may be formed of the same material as the first wiring member 151. The second lead-in member 182 may be formed of the same material as the second wiring member 152.

Also, the lead-in portion 180 has a width greater than the wiring portion 150. In detail, the width of the first lead-in member 181 is greater than that of the first wiring member 151. The sum of the widths of the second lead-in members 182 arranged at both sides of the first wiring member 151 is greater than or equal to the width of the second wiring member 152. In detail, the width of the second lead-in member 182 arranged at the left side of the first wiring member 151 is greater than or equal to the width of the second wiring member 152 connected to the second lead-in member 182. The width of the second lead-in member 182 arranged at the right side of the first wiring member 151 is greater than or equal to the width of the second wiring member 152 connected to the second lead-in member 182.

As described above, a voltage is applied to the wiring portion 150 for forming the sealing portion 170. A voltage is applied from the external power source via the lead-in portion 180. In detail, a voltage is applied to the first wiring member 151 via the first lead-in member 181. A voltage is applied to the second wiring member 152 via the second lead-in member 182.

In the case of the first wiring member 151 of FIG. 1, current flowing through an area of the first wiring member 151 corresponding to the left side of the display portion 110 and current flowing through an area of the first wiring member 151 corresponding to the right side of the display portion 110 meet at the first lead-in member 181.

That is, during the forming of the first sealing member 171, when a voltage needed to generate heat that is needed for melting is applied to the first wiring member 151, current flowing at the left and right sides of the first wiring member 151 flow together in the first lead-in member 181 so that more load is applied to the first lead-in member 181 than the first wiring member 151.

The first lead-in member 181 of the present invention has a width greater than that of the first wiring member 151 so that the generation of excessive heat is prevented. In detail, the width of the first lead-in member 181 is two times or higher than that of the first wiring member 151. Accordingly, the heat generated from the first lead-in member 181 and the head generated from the first wiring member 151 may be similar to each other.

Also, the width of the second lead-in member 182 arranged at the left side of the first lead-in member 181 is equal to or greater than that of the second wiring member 152 connected to the second lead-in member 182. The width of the second lead-in member 182 arranged at the right side of the first lead-in member 181 is equal to or greater than that of the second wiring member 152 connected to the second lead-in member 182. Thus, the heat generated from the second lead-in member 182 and the heat generated from the second wiring member 152 may be similar to each other.

In the present invention, the display portion 110 may be one of a variety of types. In the present embodiment, an organic light emitting device is applied to the display portion 110. Referring to FIG. 3, the display portion 110 is described in detail below.

A buffer layer 111 is formed on the substrate 101. The buffer layer 111 may provide a flat surface on an upper portion of the substrate 101 and prevent intrusion of moisture and foreign materials into the substrate 101.

An active layer 112 having a predetermined pattern is formed on the buffer layer 111. The active layer 112 may be formed of an inorganic semiconductor, such as amorphous silicon or polysilicon or an organic semiconductor, and includes a source region, a drain region, and a channel region.

The source and drain regions may be formed by doping impurities into the active layer 112 that is formed of the amorphous silicon or polysilicon. When the source and drain regions are doped with boron B that is a group III element, a p-type semiconductor may be formed. When the source and drain regions are doped with nitrogen N that is a group V element, an n-type semiconductor may be formed.

A gate insulation layer 113 is formed on an upper surface of the active layer 112. A gate electrode 114 is formed in a predetermine area of an upper surface of the gate insulation layer 113. The gate insulation layer 113 insulates the active layer 112 and the gate electrode 114, and may be formed of an organic material or an inorganic material such as SiNₓ or SiO₂.

The gate electrode 114 may be formed of metal such as Au, Ag, Cu, Ni, Pt, Pd, Al, Mo, or an alloy such as Al:Nd or Mo:W. However, the present invention is not limited thereto, and a variety of materials may be used considering adherence, flatness, electric resistance, and processability. The gate electrode 114 is connected to a gate line (not shown) through which an electric signal is applied.

An interlayer dielectric 115 is formed on an upper surface of the gate electrode 114. The interlayer dielectric 115 and the gate insulation layer 113 are formed so as to expose the source region and the drain region of the active layer 112. The source electrode 116 and the drain electrode 117 contact the exposed area of the active layer 112.

The material forming the source electrode 116 and the drain electrode 117 may be Au, Pd, Pt, Ni, Rh, Ru, Ir, or Os, or an alloy consisting of two or more metals such as Al, Mo, Al:Nd alloy, MoW alloy. However, the present invention is not limited thereto.

A passivation layer 118 covers the source electrode 116 and the drain electrode 117. An inorganic insulation layer and/or an organic insulation layer may be used as the passivation layer 118. The inorganic insulation layer may contain SiO₂, SiN_{X}, SiON, Al₂O₃, TiO₂, Ta₂O₅, HfO₂, ZrO₂, BST, PZT, etc. The organic insulation layer may contain general polymer PMMA or PS, a polymer derivative having a phenol group, acryl-based polymer, imide-based polymer, arylether-based polymer, amide-based polymer, fluorine-based polymer, p-xylene-based polymer, vinyl alcohol-based polymer, and a blend thereof. The passivation layer 118 may be formed as compound laminates of the inorganic insulation layer and the organic insulation layer.

The passivation layer 118 exposes the drain electrode 117 so that an organic light emitting device 120 is connected to the drain electrode 117. The organic light emitting device 120 includes a first electrode 121, a second electrode 122, and an intermediate layer 123. In detail, the first electrode 121 contacts the drain electrode 117.

The intermediate layer 123 includes an organic light emitting layer (not shown). When a voltage is applied through the first and second electrodes 121 and 122, respectively, the intermediate layer 123 emits a visible light ray.

A pixel define layer 119 is formed of an insulation material on the first electrode 121. A predetermined opening is formed in the pixel define layer 119 so as to expose the first electrode 121. The intermediate layer 123 is formed on the exposed first electrode 121. The second electrode 122 is connected to the intermediate layer 123.

The first and second electrodes 121 and 122, respectively, have polarities of an anode electrode and a cathode electrode, respectively. Of course, the polarities of the first and second electrodes 121 and 122, respectively, may be reversed. The encapsulation substrate 102 is arranged above the second electrode 122.

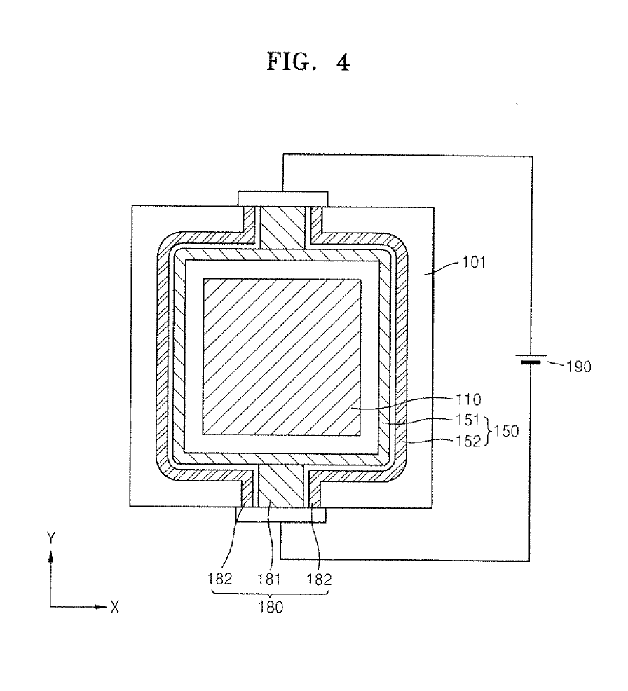

FIG. 4 is a plan view schematically illustrating an operation of applying a voltage to form a sealing portion in a process of manufacturing the flat panel display apparatus of FIG. 1.

The forming of the flat panel display apparatus 100 of FIG. 1 includes a plurality of processes, one of which is a process of forming the sealing portion 170 (FIG. 2). In the process of forming the sealing portion 170, a material for forming the sealing portion 170 is arranged and then melted and cured.

In the melting process, the opposite ends of an electric power source 190 (FIG. 4) are connected to the lead-in portion 180. When a voltage is applied to the wiring portion 150, Joule heat is generated at the wiring portion 150. Accordingly, the material for forming the sealing portion 170 arranged overlapping the wiring portion 150 is melted and then cured so that the sealing portion 170 is formed. The sealing portion 170 facilitates the coupling between the substrate 101 and the encapsulation substrate 102 (FIG. 2).

The wiring portion 150 of FIG. 4 includes the first wiring member 151 and the second wiring member 152, each having different resistance. Accordingly, the Joule heat generated from the first wiring member 151 and the Joule heat generated from the second wiring member 152 are different from each other so that the first sealing member 171 corresponding to the first wiring member 151 and the second sealing member 172 corresponding to the second wiring member 152 may be easily formed. That is, the sealing portion 170 having the first and second sealing members 171 and 172, respectively, that are formed of different materials may be easily formed.

Also, in the case of the sealing portion 170 having the first and second sealing members 171 and 172, respectively, that are formed of the same material, there is a need to generate Joule heat differently for each area according to the process conditions, the size of the substrate 101 and the characteristic of the display portion 110. In this case, according to the present invention, such a structure may be easily formed by using the first and second wiring members 151 and 152, respectively.

As a result, the sealing portion 170 exhibits a uniform characteristic so that the encapsulation characteristic of the flat panel display apparatus 100 may be improved.

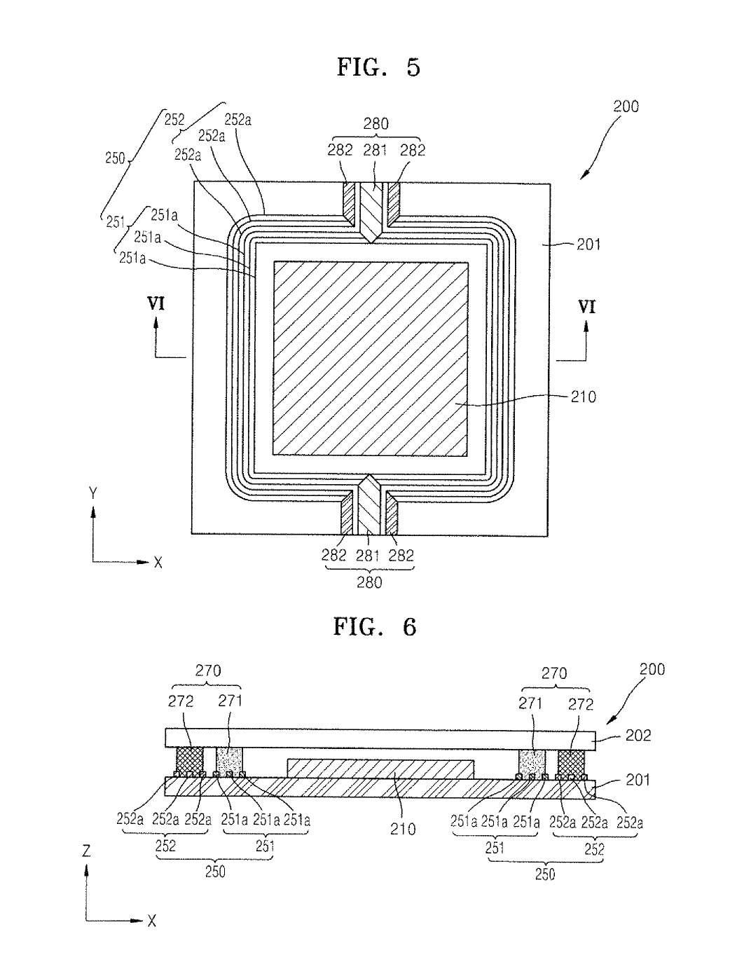

FIG. 5 is a schematic plan view of a flat panel display apparatus according to another embodiment of the present invention; and FIG. 6 is a cross-sectional view taken along line VI-VI of FIG. 5. For convenience of explanation, the following description focuses on structures and features different from those of the above-described embodiment.

Referring to FIGS. 5 and 6, the flat panel display apparatus 200 according to the present embodiment includes a substrate 201, a display portion 210, an encapsulation substrate 202, a wiring portion 250, a sealing portion 270, and a lead-in portion 280.

The display portion 210 is arranged on the substrate 201. The display portion 210 may be any one of a variety of types.

The encapsulation substrate 202 is arranged to face the display portion 210. The sealing portion 270 is arranged between the substrate 201 and the encapsulation substrate 202.

The sealing portion 270 includes a first sealing member 271 and a second sealing member 272. The first sealing member 271 surrounds the display portion 210. The first sealing member 271 facilitates coupling between the substrate 201 and the encapsulation substrate 202. The second sealing member 272 surrounds the first sealing member 271. The second sealing member 272 also facilitates coupling between the substrate 201 and the encapsulation substrate 202.

The first sealing member 271 and the second sealing member 272 may contain various materials. That is, the first sealing member 271 may contain frit and the second sealing member 272 may contain thermosetting resin. Conversely, the first sealing member 271 may contain thermosetting resin and the second sealing member 272 may contain frit.

Also, the present invention is not limited thereto and both of the first and second sealing members 271 and 272, respectively, may contain the same material.

The wiring portion 250 is arranged to overlap the sealing portion 270 and includes a first wiring member 251 and a second wiring member 252. The first wiring member 251 and the second wiring member 252 are separated from each other.

The first and second wiring members 251 and 252, respectively, of the wiring portion 250 may be formed of a variety of conductive materials, and may be formed of different materials so as to have different resistances.

That is, the first and second wiring members 251 and 252, respectively, have different resistance so that different Joule heat is generated in the first and second wiring members 251 and 252, respectively, when a voltage is applied to the first and second wiring members 251 and 252, respectively, in a subsequent process.

The first wiring member 251 surrounds the display portion 210. The second wiring member 252 surrounds the first wiring member 251. The first wiring member 251 is arranged to overlap the first sealing member 271. The second wiring member 252 is arranged to overlap the second sealing member 272.

The first wiring member 251 includes a plurality of wirings 251a. The second wiring member 252 includes a plurality of wirings 252a.

The wirings 251a of the first wiring member 251 are separated from each other in an area overlapping at least the first sealing member 271. The wirings 251a may be separated in the entire area of the first wiring member 251, as illustrated in FIG. 5.

The wirings 251a are arranged on the substrate 201. The first sealing member 271 is arranged on upper surfaces of the wirings 251a and an interval space between the neighboring wirings 251a. The encapsulation substrate 202 is arranged on the first sealing member 271.

Since the first sealing member 271 contacts the substrate 201 through the interval space between the neighboring wirings 251a, the durability of the first sealing member 271 and the coupling characteristic between the substrate 201 and the encapsulation substrate 202 may be improved.

The wirings 251a of the wiring portion 250 are described in detail. In the forming of the first sealing member 271, a material for forming the first sealing member 271 is arranged between the substrate 201 and the encapsulation substrate 202, and then, a voltage is applied to the wirings 251a of the first wiring member 251 via an external power source. Accordingly, Joule heat is generated from the wirings 251a, and thus the material is melted and then cured due to the generated heat. Thus, the first sealing member 271 is finally formed.

Since the first wiring member 251 includes the wirings 251a, rather than being integrally formed, the amount of the Joule heat applied to the center and a peripheral portion with respect to the width of the first sealing member 271 may be controlled so as to be uniform, compared to a case in which the first wiring member 251 is integrally formed to have a width corresponding to the width of the first sealing member 271. That is, uniform heat may be applied to the center and the peripheral portion with respect to the width of the first sealing member 271.

Also, in FIG. 5, the first wiring member 251 has four corner portions. That is, the wiring member 251 is bent at four corners to correspond to the corners of the display portion 210. When the first wiring member 251 is integrally formed, irregular flow of current is generated at the inner and outer sides of the corner portion, that is, in areas of the first wiring member 251 at positions close to and far from the display portion 210. That is, since a current path at the inner side of the first wiring member 251 that is integrally formed is shorter than that at the outer side thereof at the corner area, a current flow concentrates on the inner side. Accordingly, during the application of a voltage, the amount of heat generated at the inner side of the corner area of the first wiring member 251 that is integrally formed, that is, a portion facing the display portion 210, becomes abnormally large. As a result, during the application of the voltage, the material forming the first sealing member 271 may be irregularly melted and cured.

In the present embodiment, the first wiring member 251 includes the wirings 251a. That is, each wiring 251a functions as a separate current path in the corner area of the first wiring member 251. Accordingly, irregular current concentration between the inner and outer sides at the corner portion of the first wiring member 251 is not generated. In detail, the concentration of current flowing in the inner side close to the display portion 210 of the corner area of the first wiring member 251 is prevented so that, during the application of a voltage, the current may uniformly flow in the corner area of the first wiring member 251. Thus, heat is uniformly applied to the material for forming the first sealing member 271.

In particular, the first wiring member 251 may include the wiring 251a having a corner portion that is not rectangular but curved. Accordingly, the abnormal application of a voltage to the corner portion of the first wiring member 251 may be effectively prevented. Although, in FIG. 5, the corner portion of the innermost side of the wiring 251a of the first wiring member 251 is rectangular, the present invention is not limited thereto and the innermost corner portion may have a curved shape.

The wirings 252a of the second wiring member 252 are separated from each other in an area overlapping at least the second sealing member 272. As illustrated in FIG. 5, the wirings 252a may be separated from each other in the entire area.

The wirings 252a are arranged on the substrate 201. The second sealing member 272 is arranged on an upper surface of the wiring 252a and in an interval space between the neighboring wirings 252a. The encapsulation substrate 202 is arranged on the second sealing member 272.

Since the second sealing member 272 contacts the substrate 201 through the interval space between the wirings 252a, the durability of the second sealing member 272 and the coupling characteristic between the substrate 201 and the encapsulation substrate 202 may be improved.

Since the wirings 252a of the second wiring member 252 are similar to the wirings 251a of the first wiring member 251, a detailed description on the wirings 252a will be omitted herein.

The lead-in portion 280 is connected to the wiring portion 250. The lead-in portion 280 includes a first lead-in member 281 and a second lead-in member 282. The first lead-in member 281 is connected to the first wiring member 251. The second lead-in member 282 is connected to the second wiring member 252. The second lead-in member 282 is arranged at both sides of the first lead-in member 281 so as to be separated from the first lead-in member 281.

The lead-in portion 280 is connected to an external power source (not shown). Accordingly, heat is generated as a voltage is applied to the wiring portion 250 and the sealing portion 270 may be melted and then cured using the heat. The lead-in portion 280 may be formed of the same material as that of the wiring portion 250. That is, the first lead-in member 281 may be formed of the same material as that of the first wiring member 251. The second lead-in member 282 may be formed of the same material as that of the second wiring member 252.

Also, the lead-in portion 280 has a width greater than that of the wiring portion 250. In detail, the width of the first lead-in member 281 is greater than the sum of the widths of the wirings 251a of the first wiring member 251. In detail, the width of the first lead-in member 281 may be two times or greater than the sum of the widths of the wirings 251a of the first wiring member 251.

The width of the second lead-in member 282 arranged at the left side of the first lead-in member 281 is equal to or greater than the sum of the widths of the wirings 252a of the second wiring member 252 connected to the second lead-in member 282. The width of the second lead-in member 282 arranged at the right side of the first lead-in member 281 is equal to or greater than the sum of the widths of the wirings 252a of the second wiring member 252 connected to the second lead-in member 282.

An area of the lead-in portion 280 that is connected to the wiring portion 250 has an angled shape. That is, the area of the first lead-in member 281 that is connected to the first wiring member 251 has a width that decreases toward the display portion 210. Like the first lead-in member 281, an area of the second lead-in member 282 that is connected to the second wiring member 252 has a width that decreases toward the display portion 210.

Accordingly, the lengths of the wirings 251a of the first wiring member 251 may be uniformly controlled. Also, the lengths of the wirings 252a of the second wiring member 252 may be uniformly controlled. That is, the lengths of the wirings 251a of the first wiring member 251 arranged far from the display portion 210 are prevented from being remarkably longer than those of the wirings 251a arranged close to the display portion 210. Accordingly, uniform flow of current may be generated in the wirings 251a. When a voltage is applied for forming the first sealing member 271, uniform heat is generated from the wirings 251a so that uniform characteristic of the first sealing member 271 may be obtained. Like the first sealing member 271, the second sealing member 272 obtains a uniform characteristic.

In the present embodiment, the wiring portion 250 includes a first wiring member 251 and a second wiring member 252 having different resistances. Accordingly, the Joule heat generated from the first wiring member 251 and the second wiring member 252 are different from each other. The first sealing member 271 corresponding to the first wiring member 251 is easily formed. The second sealing member 272 corresponding to the second wiring member 252 is easily formed. That is, the sealing portion 270 having the first and second sealing members 271 and 271, respectively, formed of different materials may be easily formed.

Also, in the case of the sealing portion 270 having the first and second sealing members 271 and 272, respectively, that are formed of the same material, there is a need to generate Joule heat differently for each area according to the process conditions, the size of the substrate 201 and the characteristic of the display portion 210. In this case, according to the present invention, such a structure may be easily formed by using the first and second wiring members 251 and 252, respectively.

As a result, the sealing portion 270 exhibits a uniform characteristic so that the encapsulation characteristic of the flat panel display apparatus 200 may be improved.

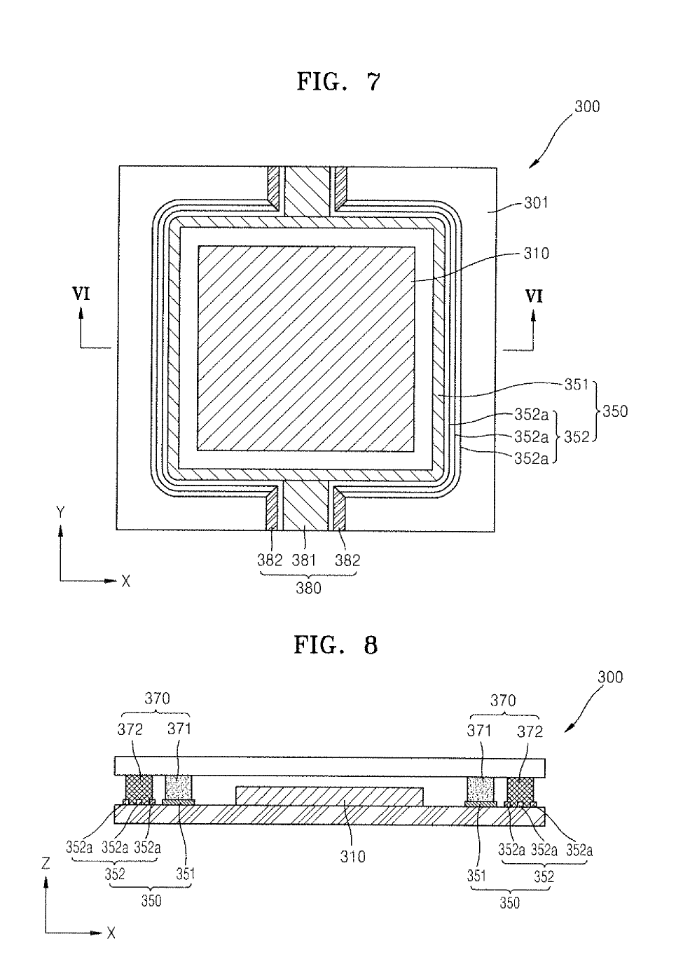

FIG. 7 is a schematic plan view of a flat panel display apparatus according to another embodiment of the present invention; and FIG. 8 is a cross-sectional view taken along line VIII-VIII of FIG. 7. For convenience of explanation, the following description focuses on structures and features different from those of the above-described embodiments.

Referring to FIGS. 7 and 8, the flat panel display apparatus 300 according to the present embodiment includes a substrate 301, a display portion 310, an encapsulation substrate 302, a wiring portion 350, a sealing portion 370, and a lead-in portion 380.

The display portion 310 is arranged on the substrate 301. The display portion 310 may be one of a variety of types.

The encapsulation substrate 302 is arranged to face the display portion 310. The sealing portion 370 is arranged between the substrate 301 and the encapsulation substrate 302.

The sealing portion 370 includes a first sealing member 371 and a second sealing member 372. The first sealing member 371 surrounds the display portion 310. The first sealing member 371 facilitates coupling between the substrate 301 and the encapsulation substrate 302. The second sealing member 372 surrounds the first sealing member 371. The second sealing member 372 also facilitates coupling between the substrate 301 and the encapsulation substrate 302.

The wiring portion 350 is arranged to overlap the sealing portion 370 and includes a first wiring member 351 and a second wiring member 352. The first wiring member 351 and the second wiring member 352 are separated from each other.

The first and second wiring members 351 and 352, respectively, of the wiring portion 350 may be formed of a variety of conductive materials and are formed of different materials so as to have different resistances.

The first wiring member 351 surrounds the display portion 310. The second wiring member 352 surrounds the first wiring member 351. The first wiring member 351 is arranged to overlap the first sealing member 371. The second wiring member 352 is arranged to overlap the second sealing member 372.

The first wiring member 351 is integrally formed. The second wiring member 352 includes a plurality of wirings 352a.

The wirings 352a of the second wiring member 352 are separated from each other in an area overlapping at least the second sealing member 372. The wirings 352a may be separated in the entire area of the second wiring member 352, as illustrated in FIG. 7.

The wirings 352a are arranged on the substrate 301. The second sealing member 372 is arranged on an upper surface of the wiring 352a and in an interval space between the neighboring wirings 352a. The encapsulation substrate 302 is arranged on the second sealing member 372.

Since the second sealing member 372 contacts the substrate 301 through the interval space between the wirings 352a, the durability of the second sealing member 372 and the coupling characteristic between the substrate 301 and the encapsulation substrate 302 may be improved.

The lead-in portion 380 is connected to the wiring portion 350. The lead-in portion 380 includes a first lead-in member 381 and a second lead-in member 382. The first lead-in member 381 is connected to the first wiring member 351. The second lead-in member 382 is connected to the second wiring member 352. The second lead-in member 382 is arranged at both sides of the first lead-in member 381 so as to be separated from the first lead-in member 381.

The lead-in portion 380 is connected to an external power source (not shown). Accordingly, heat is generated as a voltage is applied to the wiring portion 350, and the sealing portion 370 may be melted and then cured using the heat. The lead-in portion 380 may be formed of the same material as that of the wiring portion 350. That is, the first lead-in member 381 may be formed of the same material as that of the first wiring member 351. The second lead-in member 382 may be formed of the same material as that of the second wiring member 352.

Also, the lead-in portion 380 has a width greater than that of the wiring portion 350. In detail, the width of the first lead-in member 381 is greater than the width of the first wiring member 351. In further detail, the width of the first lead-in member 381 may be two times or greater than the width of the first wiring member 351.

The width of the second lead-in member 382 arranged at the left side of the first lead-in member 381 is equal to or greater than the sum of the widths of the wirings 352a of the second wiring member 352 connected to the second lead-in member 382. The width of the second lead-in member 382 arranged at the right side of the first lead-in member 381 is equal to or greater than the sum of the widths of the wirings 352a of the second wiring member 352 connected to the second lead-in member 382.

An area of the second lead-in member 382 that is connected to the wirings 352a of the second wiring member 352 has an angled shape. That is, the area of the second lead-in member 382 that is connected to the second wiring member 352 has a width that decreases toward the display portion 310.

Accordingly, the lengths of the wirings 352a of the second wiring member 352 may be uniformly controlled. That is, the lengths of the wirings 352a of the second wiring member 352 arranged far from the display portion 310 are prevented from being remarkably longer than those of the wirings 352a arranged close to the display portion 310. Accordingly, uniform flow of current may be generated in the wirings 352a. When a voltage is applied for forming the second sealing member 372, uniform heat is generated from the wirings 352a so that uniform characteristic of the second sealing member 372 may be obtained.

In the present embodiment, the first wiring member 351 of the wiring portion 350 is integrally formed and the second wiring member 352 includes wirings 352a so that the first and second wiring members 351 and 352, respectively, may be easily formed. That is, according to the characteristic of a material forming each of the first wiring member 351 and the second wiring member 352, any one of the first wiring member 351 and the second wiring member 352 is integrally formed whereas the other one includes a plurality of wirings.

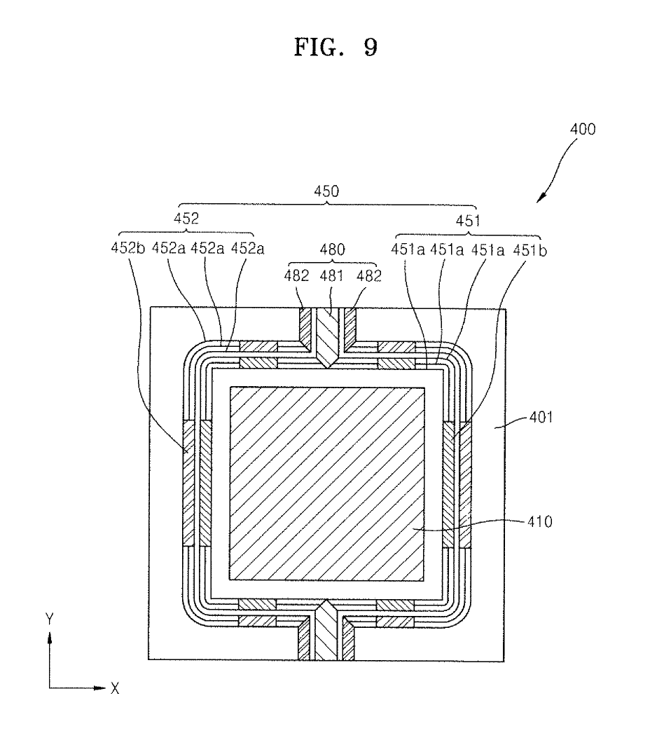

FIG. 9 is a schematic plan view of a flat panel display apparatus according to another embodiment of the present invention. For convenience of explanation, the following description focuses on structures and features different from those of the above-described embodiments. Also, a sealing portion and the encapsulation substrate are not illustrated in FIG. 9 for better understanding of the drawings and convenience of explanation.

Referring to FIG. 9, the flat panel display apparatus 400 according to the present embodiment includes a substrate 401, a display portion 410, an encapsulation substrate (not shown), a wiring portion 450, a sealing portion (not shown), and a lead-in portion 480.

The display portion 410 is arranged on the substrate 401. The display portion 410 may be one of a variety of types.

The encapsulation substrate is arranged to face the display portion 410. The sealing portion is arranged between the substrate 401 and the encapsulation substrate.

The sealing portion includes a first sealing member (not shown) and a second sealing member (not shown). The wiring portion 450 is arranged to overlap the sealing portion and includes a first wiring member 451 and a second wiring member 452. The first wiring member 451 and the second wiring member 452 are separated from each other.

The first and second wiring members 451 and 452, respectively, of the wiring portion 450 may be formed of a variety of conductive materials and are formed of different materials so as to have different resistances.

The first wiring member 451 surrounds the display portion 410. The second wiring member 452 surrounds the first wiring member 451. The first wiring member 451 is arranged to overlap the first sealing member. The second wiring member 452 is arranged to overlap the second sealing member.

The first wiring member 451 includes a plurality of wirings 451a and an integrated area 451b having an integrated shape. In detail, the wirings 451a are separated from each other and are connected to the integrated area 451b. That is, the first wiring member 451 is partially integrated and partially separated into a plurality of wirings. Also, the wirings 451a has a curved shape corresponding to a corner of the display portion 410.

The second wiring member 452 includes a plurality of wirings 452a and an integrated area 452b having an integrated shape. In detail, the wirings 452a are separated from each other and are connected to the integrated area 452b. That is, the second wiring member 452 is partially integrated and partially separated into a plurality of wirings. Also, the wirings 452a have a curved shape corresponding to a corner of the display portion 410.

The wirings 451a of the first wiring member 451 are separated from each other in an area overlapping at least the first sealing member.

The wirings 451a are arranged on the substrate 401. The first sealing member is arranged on upper surfaces of the wirings 451a and an interval space between the neighboring wirings 451a. The encapsulation substrate is arranged on the first sealing member.

Since the first sealing member contacts the substrate 401 through the interval space between the neighboring wirings 451a, the durability of the first sealing member and the coupling characteristic between the substrate 401 and the encapsulation substrate may be improved.

Since the structure of the wirings 452a of the second wiring member 452 is similar to the above-described structure of the first wiring member 451, a detailed description thereof will be omitted herein.

The lead-in portion 480 is connected to the wiring portion 450. The lead-in portion 480 includes a first lead-in member 481 and a second lead-in member 482. The first lead-in member 481 is connected to the first wiring member 451. The second lead-in member 482 is connected to the second wiring member 452. The second lead-in member 482 is arranged at both sides of the first lead-in member 481 so as to be separated from the first lead-in member 481.

The lead-in portion 480 is connected to an external power source (not shown). Accordingly, heat is generated as a voltage is applied to the wiring portion 450, and the sealing portion may be melted and then cured using the heat. The lead-in portion 480 may be formed of the same material as that of the wiring portion 450. That is, the first lead-in member 481 may be formed of the same material as that of the first wiring member 451. The second lead-in member 482 may be formed of the same material as that of the second wiring member 452.

Also, the lead-in portion 480 has a width greater than that of the wiring portion 450. In detail, the width of the first lead-in member 481 is greater than the width of the first wiring member 451. For example, the width of the first lead-in member 481 may be two times or greater than the width of the integrated area 451b of the first wiring member 451.

The width of the second lead-in member 482 arranged at the left side of the first lead-in member 481 is equal to or greater than the width of the integrated area 452b of the second wiring member 452 connected to the second lead-in member 482. The width of the second lead-in member 482 arranged at the right side of the first lead-in member 481 is equal to or greater than the width of the integrated area 452b of the second wiring member 452 connected to the second lead-in member 482.

An area of the first lead-in portion 481 that is connected to the wirings 451a of the first wiring member 451 has an angled shape. That is, the area of the first lead-in member 481 that is connected to the first wiring member 451 has a width that decreases toward the display portion 410.

Also, an area of the second lead-in portion 482 that is connected to the wirings 452a of the second wiring member 452 has an angled shape. That is, the area of the second lead-in member 482 that is connected to the second wiring member 452 has a width that decreases toward the display portion 410.

In the present embodiment, each of the first and second wiring members 451 and 452, respectively, of the wiring portion 450 includes a plurality of wirings 451a and 452a corresponding to an area that corresponds to a corner of the display portion 410. In particular, since the wirings 451a and 452a have a curved shape, the concentration of current flowing in the inner side close to the display portion 410 of the corner areas of the first and second wiring members 451 and 452, respectively, is prevented so that, during the application of a voltage, the current may uniformly flow in the corner areas of the first and second wiring members 451 and 452, respectively. Thus, the first and second sealing members may be uniformly heated.

Also, since the first and second wiring members 451 and 452, respectively, include the integrated areas 451b and 452b that are connected to the wirings 451a and 452a of the first and second wiring members 451 and 452, respectively, the wirings 451a and 452a may be firmly fixed. Thus, the durability of the first and second wiring members 451 and 452, respectively, may be improved.

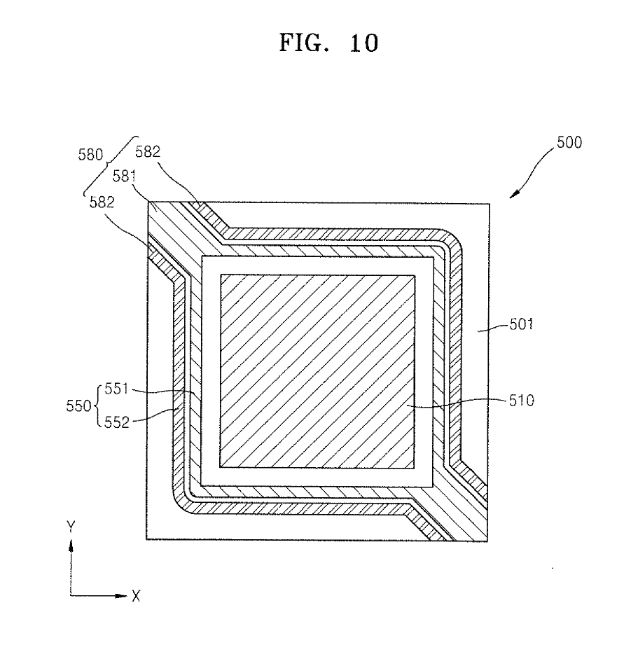

FIG. 10 is a schematic plan view of a flat panel display apparatus according to another embodiment of the present invention. For convenience of explanation, the following description focuses on structures and features different from those of the above-described embodiments.

Referring to FIG. 10, the flat panel display apparatus 500 according to the present embodiment includes a substrate 501, a display portion 510, an encapsulation substrate (not shown), a wiring portion 550, a sealing portion (not shown), and a lead-in portion 580.

The display portion 510 is arranged on the substrate 501. The encapsulation substrate is arranged to face the display portion 510. The sealing portion is arranged between the substrate 501 and the encapsulation substrate.

The sealing portion includes a first sealing member (not shown) and a second sealing member (not shown). The wiring portion 550 is arranged to overlap the sealing portion and includes a first wiring member 551 and a second wiring member 552. The first wiring member 551 and the second wiring member 552 are separated from each other.

The first and second wiring members 551 and 552, respectively, of the wiring portion 550 may be formed of a variety of conductive materials, and are formed of different materials so as to have different resistances.

The first wiring member 551 surrounds the display portion 510. The second wiring member 552 surrounds the first wiring member 551. The first wiring member 551 is arranged to overlap the first sealing member. The second wiring member 552 is arranged to overlap the second sealing member.

The lead-in portion 580 is connected to the wiring portion 550. The lead-in portion 580 includes a first lead-in member 581 and a second lead-in member 582. The first lead-in member 581 is connected to the first wiring member 551. The second lead-in member 582 is connected to the second wiring member 552. The second lead-in member 582 is arranged at both sides of the first lead-in member 581 so as to be separated from the first lead-in member 581.

The lead-in portion 580 may be formed of the same material as that of the wiring portion 550. That is, the first lead-in member 581 may be formed of the same material as that of the first wiring member 551. The second lead-in member 582 may be formed of the same material as that of the second wiring member 552.

The lead-in portion 580 is formed to correspond to a corner of the display portion 510 and the opposite corner thereto. Also, the lead-in portion 580 is formed to correspond to a corner of the substrate 501 and the opposite corner thereto. Accordingly, the space for arrangement of an external power source needed to perform a process for forming the sealing member may be reduced.

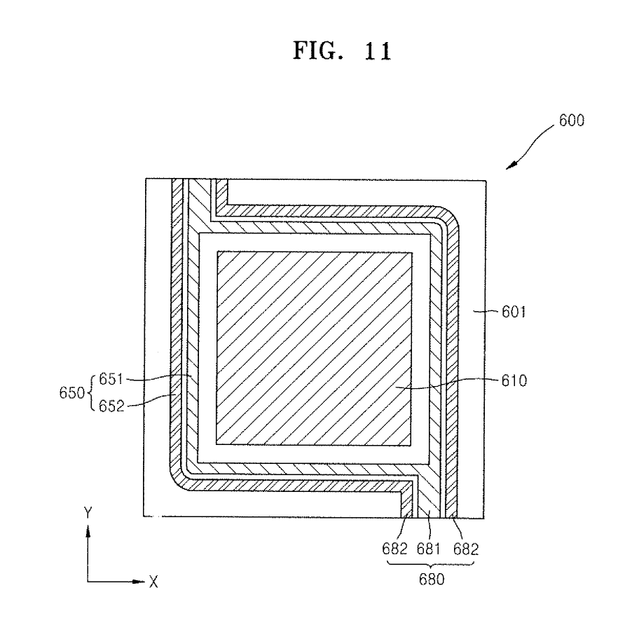

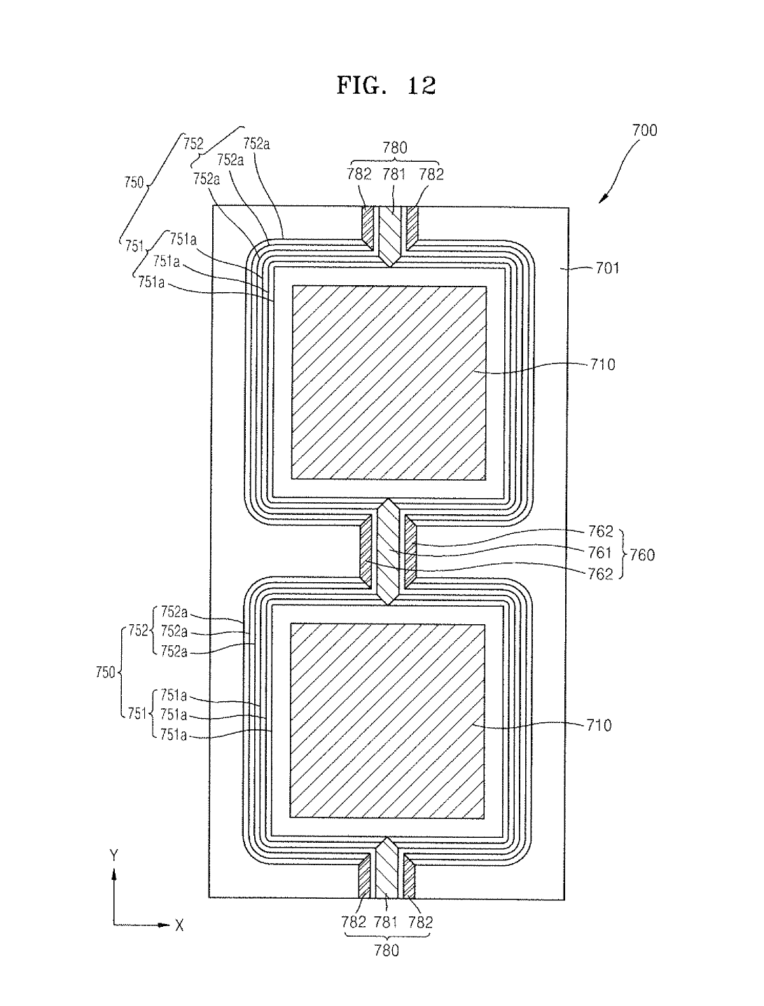

FIG. 11 is a schematic plan view of a flat panel display apparatus according to another embodiment of the present invention. For convenience of explanation, the following description focuses on structures and features different from those of the above-described embodiments.

Referring to FIG. 11, the flat panel display apparatus 600 according to the present embodiment includes a substrate 601, a display portion 610, an encapsulation substrate (not shown), a wiring portion 650, a sealing portion (not shown), and a lead-in portion 680.

The flat panel display apparatus 600 according to the present embodiment is the same as the flat panel display apparatus 500 of FIG. 10 except for the arrangement or position of the lead-in portion 680.

The lead-in portion 680 is formed to correspond to a corner of the display portion 610 and the opposite corner thereto. Accordingly, the space for arrangement of an external power source needed to perform a process for forming the sealing member may be reduced.

Also, the lead-in portion 680 is formed parallel to the wiring portion 650. That is, the first lead-in member 681 is formed parallel to an area of the first wiring member 651. The second lead-in member 682 is formed parallel to an area of the second wiring member 652.

Accordingly, a process for integrally forming the first lead-in member 681 and the first wiring member 651 may be facilitated. A process for integrally forming the second lead-in member 682 and the second wiring member 652 may also be facilitated.

FIG. 12 is a schematic plan view of a mother substrate for a flat panel display apparatus according to an embodiment of the present invention. For convenience of explanation, the following description focuses on structures and features different from those of the above-described embodiments.

Referring to FIG. 12, the mother substrate 700 for a flat panel display apparatus according to the present embodiment includes a substrate 701, a plurality of display portions 710, an encapsulation substrate (not shown), a wiring portion 750, a sealing portion (not shown), and a lead-in portion 780.

The display portions 710 are arranged on the substrate 701. The display portions 710 are provided in a plural number, and each display portion 710 constitutes a flat panel display apparatus. Since FIG. 12 illustrates two display portions 710, two flat panel display apparatuses may be finally manufactured from the mother substrate 700 for a flat panel display apparatus according to the present embodiment. However, the present invention is not limited thereto, and there is no limit to the number of display portions provided on the mother substrate 700 for a flat panel display apparatus.

The encapsulation substrate is arranged to face the display portions 710. The sealing portion is arranged between the substrate 701 and the encapsulation substrate. The sealing portion surrounds each display portion 710. In detail, the sealing portion includes a first sealing member (not shown) and a second sealing member (not shown). The first sealing member surrounds the display portions 710 and the second sealing member is arranged around the first sealing member.

The wiring portion 750 is formed to overlap the sealing portion. The wiring portion 750 is provided in a plural number, and each wiring portion 750 surrounds each display portion 710. That is, in the present embodiment, two wiring portions 750 are provided in correspondence to the display portion 710.

Also, each wiring portion 750 includes a first wiring member 751 and a second wiring member 752. The first wiring member 751 and the second wiring member 752 are separated from each other.

The first wiring member 751 surrounds the display portion 710. The second wiring member 752 surrounds the first wiring member 751. The first wiring member 751 is arranged to overlap the first sealing member. The second wiring member 752 is arranged to overlap the second sealing member.

The first wiring member 751 includes a plurality of wirings 751a. The second wiring member 752 includes a plurality of wirings 752a.

The wirings 751a of the first wiring member 751 are separated from each other in an area overlapping at least the first sealing member. As illustrated in FIG. 12, the wirings 751a may be arranged so as to be separated from each other in the entire area.

The wirings 751a are arranged on the substrate 701. The first sealing member is arranged on upper surfaces of the wirings 751a and an interval space between the neighboring wirings 751a. The encapsulation substrate is arranged on the first sealing member. Since the other structure of the wiring portion is similar to that of the wiring portion 250 of FIG. 5, a detailed description thereof will be omitted herein.

The two wiring portions 750 of FIG. 12 are arranged in one direction, that is, in a direction of the Y-axis of FIG. 12. A connection portion 760 is arranged between the neighboring wiring portions 750 adjacent in the direction of the Y-axis. The connection portion 760 connects the neighboring wiring portions 750. The connection portion 760 contains a conductive material and may be formed of the same material as that of the wiring portion 750.

The connection portion 760 includes a first connection member 761 and a second connection member 762. The first connection member 761 is connected to the first wiring member 751. The second connection member 762 is arranged at both sides of the first connection member 761 and is connected to the second wiring member 752.

The connection portion 760 has a width greater than that of the wiring portion 750. In detail, the width of the first connection member 761 is greater, particularly two times or greater, than the sum of the widths of the wirings 751a of the first wiring member 751. The width of the second connection member 762 arranged at the left side of the first connection member 761 is equal to or greater than the sum of the widths of the wirings 752a of the second wiring member 752 connected to the second connection member 762. The width of the second connection member 762 arranged at the right side of the first connection member 761 is equal to or greater than the sum of the widths of the wirings 752a of the second wiring member 752 connected to the second connection member 762.

An area of the connection portion 760 that is connected to the wiring portion 750 has an angled shape. That is, the area of the first connection member 761 that is connected to the first wiring member 751 has a width that decreases toward the display portion 710. Like the first connection member 761, the area of the second connection member 762 that is connected to the second wiring member 752 has a width that decreases toward the display portion 710.

Accordingly, the lengths of the wirings 751a of the first wiring member 751 and the wirings 752a of the second wiring member 752 may be uniformly controlled. That is, the lengths of the wirings 751a arranged far from the display portion 710 of the first wiring member 751 are prevented from being remarkably longer than those of the wirings 751a arranged close to the display portion 310. Accordingly, uniform flow of current may be generated in the wirings 751a. When a voltage is applied for forming the first sealing member, uniform heat is generated from the wirings 751a so that a uniform characteristic of the first sealing member may be obtained. Likewise, the second sealing member may obtain a uniform characteristic.

The lead-in portion 780 is connected to the wiring portion 750. In detail, the lead-in portion 780 is formed at the upper and lower ends of the substrate 701. The lead-in portion 780 includes a first lead-in member 781 and a second lead-in member 782. The first lead-in member 781 is connected to the first wiring member 751. The second lead-in member 782 is connected to the second wiring member 752. The second lead-in member 782 is arranged at both sides of the first lead-in member 781 so as to be separated from the first lead-in member 781.

Since the other detailed structure of the lead-in portion 780 is similar to that of the lead-in portion 280 of FIG. 5, a detailed description thereof will be omitted herein.

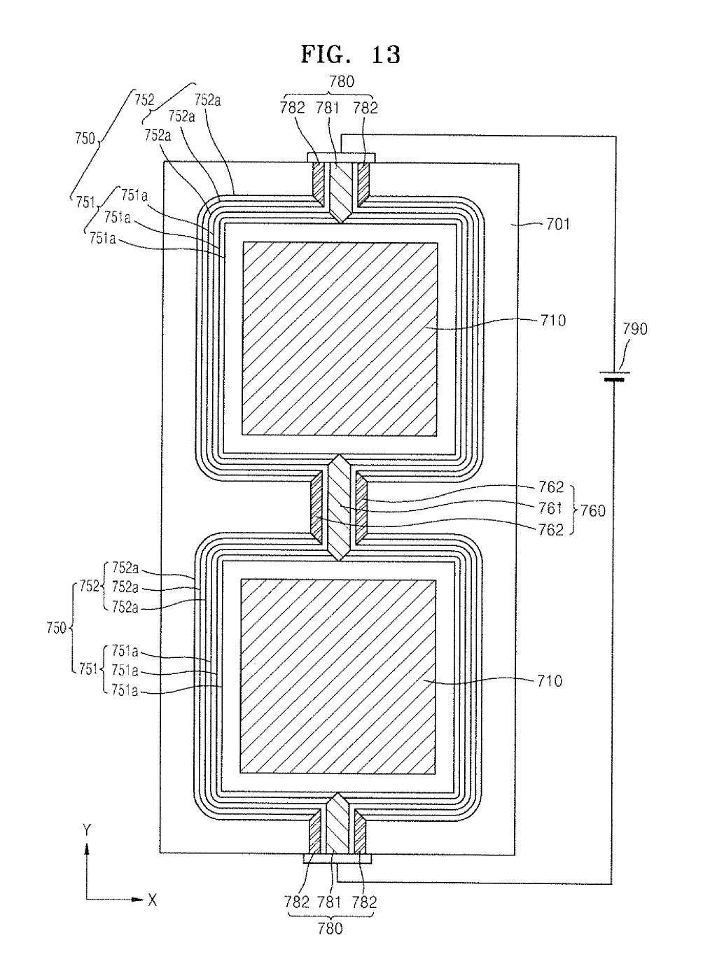

FIG. 13 is a plan view schematically illustrating an operation of forming the sealing portion in a process of manufacturing the mother substrate for a flat panel display apparatus of FIG. 12. In detail, FIG. 13 illustrates a process of applying a voltage through an external power source 790 to form a sealing member 770.

The process of forming the mother substrate 700 for a flat panel display apparatus of FIG. 12 includes a plurality of operations. Among the operations, the forming of the sealing portion includes arranging a material for forming the sealing portion and melting and curing the material. For example, the first sealing member contains frit and the second sealing member contains thermosetting resin. Frit paste is used to form the first sealing member and thermosetting resin is used to form the second sealing member. Then, the frit paste and the thermosetting resin are simultaneously melted and cured. However, the present invention is not limited thereto, and the first and second sealing members may be formed of the same material.

In the melting process, the opposite ends of the external power source 790 are connected to the lead-in portion 780. When a voltage generated by the external power source 790 is applied to the wiring portion 750 through the lead-in portion 780, Joule heat is generated in the wiring portion 750. That is, the first and second sealing members are easily formed by making different Joule heat generated from the first and second wiring members 751 and 752, respectively, having different resistance.

Although it is not illustrated, a flat panel display apparatus may be finally manufactured by cutting each display portion 710 and the sealing member surrounding the display portion 710 in the subsequent operation.

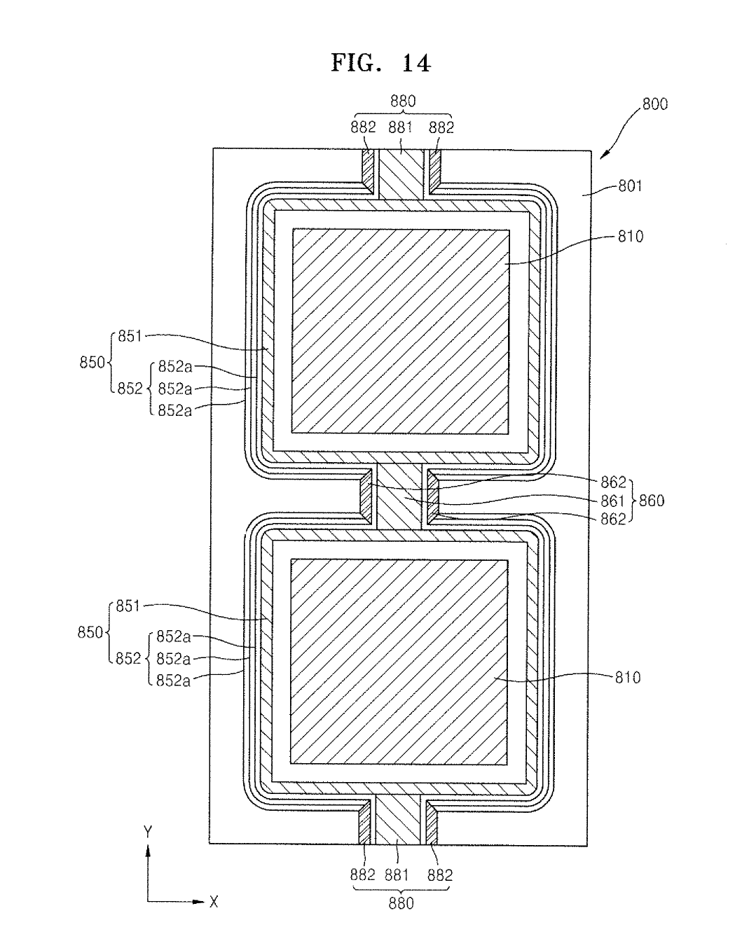

FIG. 14 is a schematic plan view of a mother substrate for a flat panel display apparatus according to another embodiment of the present invention. For convenience of explanation, the encapsulation substrate and the sealing portion are not illustrated in FIG. 14.

Referring to FIG. 14, the mother substrate 800 for a flat panel display apparatus according to the present embodiment includes a substrate 801, a plurality of display portions 810, an encapsulation substrate (not shown), a wiring portion 850, a sealing portion (not shown), a connection portion 860, and a lead-in portion 880.

The display portion 810 is arranged on the substrate 801. Each display portion 810 constitutes a flat panel display apparatus. Since FIG. 14 illustrates two display portions 810, two flat panel display apparatuses may be finally manufactured from the mother substrate 800 for a flat panel display apparatus according to the present embodiment. However, the present invention is not limited thereto, and there is no limit to the number of the display portions 810 provided on the mother substrate 800 for a flat panel display apparatus.

The encapsulation substrate is arranged to face a plurality of the display portions 810. The sealing portion is arranged between the substrate 801 and the encapsulation substrate. The sealing portion surrounds each display portion 810. In detail, the sealing portion includes a first sealing member (not shown) and a second sealing member (not shown).

The wiring portion 850 is formed to overlap the sealing portion. The wiring portion 850 is provided in a plural number, and each wiring portion 850 surrounds each display portion 810. That is, in the present embodiment, two wiring portions 850 are provided in correspondence to the display portion 810.

Also, each wiring portion 850 includes a first wiring member 851 and a second wiring member 852. The first wiring member 851 and the second wiring member 852 are separated from each other.

The first wiring member 851 surrounds the display portion 810. The second wiring member 852 surrounds the first wiring member 851. The first wiring member 851 is arranged to overlap the first sealing member. The second wiring member 852 is arranged to overlap the second sealing member.

The first wiring member 851 is an integrated shape. The second wiring member 852 includes a plurality of wirings 852a.

The wirings 852a of the second wiring member 852 are separated from each other in an area overlapping at least the second sealing member. As illustrated in FIG. 14, the wirings 852a may be arranged so as to be separated from each other in the entire area.

The wirings 852a are arranged on the substrate 801. The second sealing member is arranged on upper surfaces of the wirings 852a and an interval space between the neighboring wirings 852a. Since the other structure of the wiring portion is similar to that of the wiring portion 250 of FIG. 5, a detailed description thereof will be omitted herein.

The two wiring portions 850 of FIG. 14 are arranged in one direction, that is, in a direction of the Y-axis of FIG. 14. The connection portion 860 connects the neighboring wiring portions 850. The connection portion 860 contains a conductive material and may be formed of the same material as that of the wiring portion 850.

The connection portion 860 includes a first connection member 861 and a second connection member 862. The first connection member 861 is connected to the first wiring member 851. The second connection member 862 is arranged at both sides of the first connection member 861 and is connected to the second wiring member 852.

The connection portion 860 has a width greater than that of the wiring portion 850. In detail, the width of the first connection member 861 is greater, particularly two times or greater, than the width of the first wiring member 851. The width of the second connection member 862 arranged at the left side of the first connection member 861 is equal to or greater than the sum of the widths of the wirings 852a of the second wiring member 852 connected to the second connection member 862. The width of the second connection member 862 arranged at the right side of the first connection member 861 is equal to or greater than the sum of the widths of the wirings 852a of the second wiring member 852 connected to the second connection member 862.

The area of the second connection member 862 that is connected to the wirings 852a of the second wiring member 852 has an angled shape. That is, the area of the second connection member 862 that is connected to the second wiring member 852 has a width that decreases toward the display portion 810.

The lead-in portion 880 is connected to the wiring portion 850. In detail, the lead-in portion 880 is formed at the upper and lower ends of the substrate 801. The lead-in portion 880 includes a first lead-in member 881 and a second lead-in member 882. The first lead-in member 881 is connected to the first wiring member 851. The second lead-in member 882 is connected to the second wiring member 852. The second lead-in member 882 is arranged at both sides of the first lead-in member 881 so as to be separated from the first lead-in member 881.

Since the other detailed structure of the lead-in portion 880 is similar to that of the lead-in portion 380 of FIG. 7, a detailed description thereof will be omitted herein.

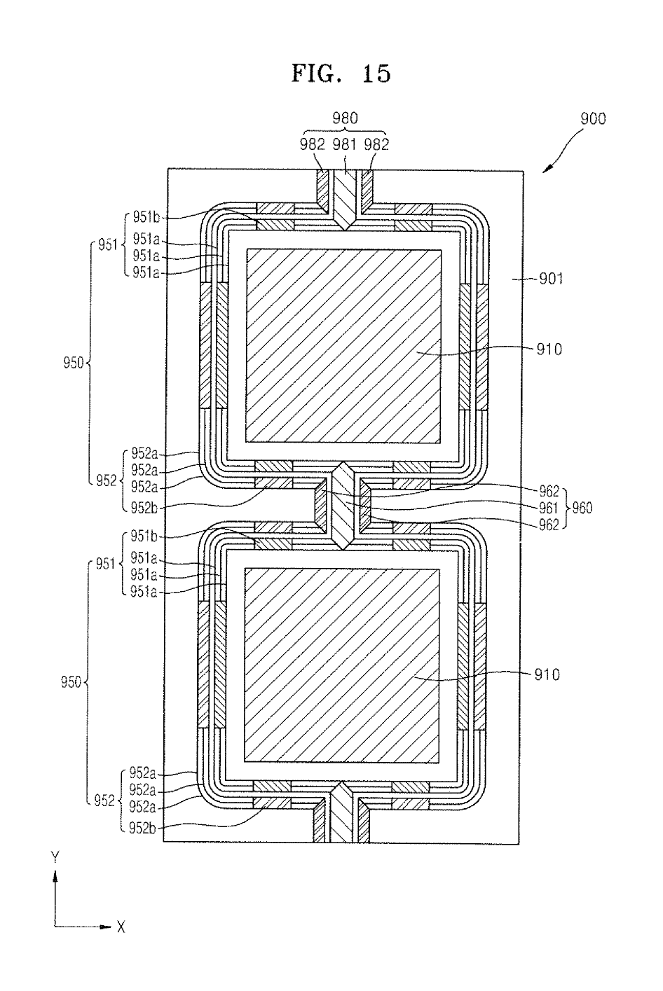

FIG. 15 is a schematic plan view of a mother substrate for a flat panel display apparatus according to another embodiment of the present invention. For convenience of explanation, the encapsulation substrate and the sealing portion are not illustrated in FIG. 15.

Referring to FIG. 15, the mother substrate 900 for a flat panel display apparatus according to the present embodiment includes a substrate 901, a plurality of display portions 910, an encapsulation substrate (not shown), a wiring portion 950, a sealing portion (not shown), a connection portion 960, and a lead-in portion 980.

The display portion 910 is arranged on the substrate 901. Each display portion 910 constitutes a flat panel display apparatus. Since FIG. 15 illustrates two display portions 910, two flat panel display apparatuses may be finally manufactured from the mother substrate 900 for a flat panel display apparatus according to the present embodiment. However, the present invention is not limited thereto, and there is no limit to the number of the display portions 910 provided on the mother substrate 900 for a flat panel display apparatus.

The encapsulation substrate is arranged to face a plurality of the display portions 910. The sealing portion is arranged between the substrate 901 and the encapsulation substrate. The sealing portion surrounds each display portion 910. In detail, the sealing portion includes a first sealing member (not shown) and a second sealing member (not shown).

The wiring portion 950 is formed so as to overlap the sealing portion. The wiring portion 950 is provided in a plural number, and each wiring portion 950 surrounds each display portion 910. That is, in the present embodiment, two wiring portions 950 are provided in correspondence to the display portion 910.

Also, each wiring portion 950 includes a first wiring member 951 and a second wiring member 952. The first wiring member 951 and the second wiring member 952 are separated from each other.

The first wiring member 951 surrounds the display portion 910. The second wiring member 952 surrounds the first wiring member 951. The first wiring member 951 is arranged to overlap the first sealing member. The second wiring member 952 is arranged to overlap the second sealing member.

The first wiring member 951 is an integrated area 951b having an integrated shape and a plurality of wirings 951a. In detail, the wirings 951a are separated from each other and are connected to the integrated area 951a. That is, the first wiring member 951 is partially integrated and partially formed of a plurality of wirings. The wirings 951a correspond to a corner of the display portion 910 and have a bent shape.

The second wiring member 952 includes an integrated area 952b having an integrated shape and a plurality of wirings 952a. In detail, the wirings 952a are separated from each other and are connected to the integrated area 952b. That is, the second wiring member 952 is partially integrated and partially formed of a plurality of wirings. The wirings 952a correspond to a corner of the display portion 910 and have a bent shape.

The two wiring portions 950 of FIG. 15 are arranged in one direction, that is, in a direction of the Y-axis of FIG. 15. The connection portion 960 is arranged between the neighboring wiring portions 950 in the direction of the Y-axis. The connection portion 960 contains a conductive material and may be formed of the same material as that of the wiring portion 950.

The connection portion 960 includes a first connection member 961 and a second connection member 962. The first connection member 961 is connected to the first wiring member 951. The second connection member 962 is arranged at both sides of the first connection member 961 and is connected to the second wiring member 952.

The connection portion 960 has a width greater than that of the wiring portion 950. In detail, the width of the first connection member 961 is greater than that of the first wiring member 951, particularly two times or greater than the width of the integrated area 951b of the first wiring member 951.

The width of the second connection member 962 arranged at the left side of the first connection member 961 is equal to or greater than the width of the integrated area 952b of the second wiring member 952 connected to the second connection member 962. The width of the second connection member 962 arranged at the right side of the first connection member 961 is equal to or greater than the width of the integrated area 952b of the second wiring member 952 connected to the second connection member 962.

The area of the first connection member 961 that is connected to the wirings 951a of the first wiring member 951 has an angled shape. That is, the area of the first connection member 961 that is connected to the first wiring member 951 has a width that decreases toward the display portion 910.

the area of the second connection member 962 that is connected to the wirings 952a of the second wiring member 952 has an angled shape. That is, the area of the second connection member 962 that is connected to the second wiring member 952 has a width that decreases toward the display portion 910.

The lead-in portion 980 is connected to the wiring portion 950. In detail, the lead-in portion 980 is formed at the upper and lower ends of the substrate 901. The lead-in portion 980 includes a first lead-in member 981 and a second lead-in member 982. The first lead-in member 981 is connected to the first wiring member 951. The second lead-in member 982 is connected to the second wiring member 952. The second lead-in member 982 is arranged at both sides of the first lead-in member 981 so as to be separated from the first lead-in member 981.

Since the other detailed structure of the lead-in portion 980 is similar to that of the lead-in portion 480 of FIG. 9, a detailed description thereof will be omitted herein.

Although it is not illustrated in FIG. 15, the present invention includes a mother substrate for a flat panel display apparatus having the shape of FIG. 1, that is, a shape in which the first and second wiring members 951 and 952, respectively, are integrated.

Also, the present invention may include a mother substrate for a flat panel display apparatus in which the lead-in portion as illustrated in FIGS. 10 and 11 is arranged to correspond to the corner of the display portion, or the connection portion is arranged to correspond to the corner of the display portion.

As described above, according to the flat panel display apparatus, the mother substrate for a flat panel display apparatus, the method of manufacturing a flat panel display apparatus, and the method of manufacturing a mother substrate for a flat panel display apparatus according to the present invention, an encapsulation characteristic may be easily improved.

While this invention has been particularly shown and described with reference to exemplary embodiments thereof, it will be understood by those skilled in the art that various changes in form and detail may be made therein without departing from the spirit and scope of the invention as defined by the appended claims.

What is claimed is:

1. A flat panel display apparatus, comprising:
a substrate;
a display portion arranged on the substrate;
an encapsulation substrate arranged to face the display portion;
a sealing portion arranged between the substrate and the encapsulation substrate, and surrounding the display portion;
a wiring portion arranged between the substrate and the encapsulation substrate so as to have an area overlapping the sealing portion, and comprising a plurality of wiring members having different respective resistances; and
a lead-in portion electrically connected to an external power source and connected to the wiring portion for applying a voltage to the wiring portion.

2. The flat panel display apparatus of claim 1, wherein the sealing portion comprises a plurality of sealing members corresponding to respective wiring members.

3. The flat panel display apparatus of claim 2, wherein the plurality of sealing members are formed of different materials.

4. The flat panel display apparatus of claim 2, wherein the plurality of sealing members are formed of a same material.

5. The flat panel display apparatus of claim 1, wherein the lead-in portion comprises a plurality of lead-in members corresponding to respective wiring members.

6. The flat panel display apparatus of claim 5, wherein the lead-in members are separated from each other.

7. The flat panel display apparatus of claim 1, wherein the wiring members are separated from each other.

8. The flat panel display apparatus of claim 1, wherein the plurality of wiring members comprise:
a first wiring member surrounding the display portion; and
a second wiring member surrounding at least the first wiring portion.

9. The flat panel display apparatus of claim 8, wherein the lead-in portion comprises:
a first lead-in member corresponding to the first wiring member; and
a second lead-in member corresponding to the second wiring member;
wherein the second lead-in member is arranged at both sides of the first lead-in member.

10. The flat panel display apparatus of claim 1, wherein each of the wiring members comprises a plurality of wirings.

11. The flat panel display apparatus of claim 10, wherein the wirings are separated from each other.

12. The flat panel display apparatus of claim 10, wherein the wirings are formed on the substrate, and the sealing portion is arranged on an upper surface of the wiring portion and in an interval space between neighboring wirings of the plurality of wirings.

13. The flat panel display apparatus of claim 10, wherein the plurality of wirings comprise a wiring having a curved corner portion.

14. The flat panel display apparatus of claim 10, wherein an area of the lead-in portion connected to the plurality of wirings has a width which decreases toward the display portion so as to have an angled shape.

15. The flat panel display apparatus of claim 1, wherein at least one of the wiring members comprises a plurality of wirings and at least one of the wiring members is integrally formed.

16. The flat panel display apparatus of claim 15, wherein an area of the lead-in portion connected to the plurality of wirings has a width which decreases toward the display portion so as to have an angled shape.

17. The flat panel display apparatus of claim 1, wherein at least one of the wiring members comprises an integrated area that is integrally formed at least in a partial area, and includes a plurality of wirings that are connected to the integrated area and are separated from each other.

18. The flat panel display apparatus of claim 17, wherein the wirings that are separated from each other are arranged so as to correspond to corners of the display portion.

19. The flat panel display apparatus of claim 17, wherein the wirings that are separated from each other are formed so as to be bent.

20. The flat panel display apparatus of claim 17, wherein the wirings that are separated from each other are connected to the lead-in portion.

21. The flat panel display apparatus of claim 20, wherein an area of the lead-in portion that is connected to the wirings has a width which decreases toward the display portion so as to have an angled shape.

22. The flat panel display apparatus of claim 1, wherein the lead-in portion is formed so as to correspond to one corner of the display portion and another corner of the display portion.

23. The flat panel display apparatus of claim 22, wherein the lead-in portion is symmetrically arranged with respect to a center of the display portion.

24. The flat panel display apparatus of claim 1, wherein the lead-in portion is formed so as to have a width greater than a width of the wiring portion.

25. The flat panel display apparatus of claim 1, wherein the display portion comprises an organic light emitting device.

26. A mother substrate for a flat panel display apparatus, the mother substrate comprising:
a substrate;
a plurality of display portions arranged on the substrate and separated from each other so as to form a plurality of flat panel display apparatuses;
an encapsulation substrate arranged to face the plurality of display portions;
a plurality of sealing portions arranged between the substrate and the encapsulation substrate, and surrounding each of the display portions;
a plurality of wiring portions arranged between the substrate and the encapsulation substrate, and having an area overlapping each of the plurality of sealing portions, each wiring portion comprising a plurality of wiring members having different respective resistances;
a connection portion containing a conductive material and connecting wiring portions that are adjacent to each other in one direction; and
a lead-in portion connected to the plurality of wiring portions and to an external power source for applying a voltage to the plurality of wiring portions.

27. The mother substrate for a flat panel display apparatus of claim 26, wherein the connection portion comprises a plurality of connection members corresponding to respective wiring members.

28. The mother substrate for a flat panel display apparatus of claim 27, wherein the connection members are separated from each other.

29. The mother substrate for a flat panel display apparatus of claim 26, wherein at least one of the plurality of wiring members comprises a plurality of wirings, and an area of the connection portion that is connected to the plurality of wirings has a width which decreases toward the display portion so as to have an angled shape.

30. The mother substrate for a flat panel display apparatus of claim 26, wherein at least one of the plurality of wiring members comprises an integrated area that is integrally formed in at least one area and a plurality of wirings separated from each other in at least one area.

31. The mother substrate for a flat panel display apparatus of claim 30, wherein an area of the connection portion that is connected to the plurality of wirings has a width which decreases toward the display portion so as to have an angled shape.

32. The mother substrate for a flat panel display apparatus of claim 26, wherein the connection portion has a width greater than a width of the wiring portion.

33. A method of manufacturing a flat panel display apparatus, the method comprising the steps of:
preparing a substrate on which a display portion is arranged;
arranging an encapsulation substrate to face the display portion;
forming a sealing portion between the substrate and the encapsulation substrate so as to surround the display portion;
forming a wiring portion between the substrate and the encapsulation substrate so as to overlap at least the sealing portion, the wiring portion comprising a plurality of wiring members having different respective resistances; and
forming a lead-in portion electrically connected to an external power source and to the wiring portion;
wherein the step of forming the sealing portion comprises:
arranging a material for forming the sealing portion between the substrate and the encapsulation substrate;
electrically connecting the external power source to the lead-in portion;
applying a voltage generated from the external power source to the wiring portion through the lead-in portion; and
melting and curing the material for forming the sealing portion using heat generated from the wiring portion.

34. The method of manufacturing a flat panel display apparatus of claim 33, wherein the step of forming the sealing portion comprises forming a plurality of sealing members respectively corresponding to the plurality of wiring members.

35. A method of manufacturing a flat panel display apparatus, the method comprising the steps of:
preparing a substrate on which a plurality of display portions are arranged to form a plurality of flat panel display apparatuses;
arranging an encapsulation substrate so as to face the plurality of display portions;
forming a sealing portion between the substrate and the encapsulation substrate so as to surround each display portion;
forming a plurality of wiring portions between the substrate and the encapsulation substrate so as to overlap at least the sealing portion, each of the wiring portions comprising a plurality of wiring members having different respective resistances;
forming a connection portion containing a conductive material and arranged to connect wiring portions that are adjacent to each other in one direction; and
forming a lead-in portion electrically connected to an external power source and the plurality of wiring portions;
wherein the step of forming the sealing portion comprises:
arranging a material for forming the sealing portion between the substrate and the encapsulation substrate;
electrically connecting the external power source to the lead-in portion;
applying a voltage generated from the external power source to the plurality of wiring portions through the lead-in portion; and
melting and curing the material for forming the sealing portion using heat generated from the plurality of wiring portions.

36. The method of manufacturing a mother substrate for a flat panel display apparatus of claim 35, wherein the step of forming the sealing portion comprises forming a plurality of sealing members respectively corresponding to the plurality of wiring members.
